(19) United States
(12) Patent Application Publication
(10) Pub. No.: US 2024/0224747 A1
(43) Pub. Date: Jul. 4, 2024

(54) DISPLAY DEVICE

(71) Applicant: LG Display Co., Ltd., Seoul (KR)

(72) Inventors: Tae-Kung RYOO, Paju-si (KR); Sang-Bin LEE, Paju-si (KR); Hyuk-Chan GEE, Paju-si (KR)

(21) Appl. No.: 18/538,992

(22) Filed: Dec. 13, 2023

(30) Foreign Application Priority Data
Dec. 29, 2022 (KR) 10-2022-0189150

(51) Int. Cl. H10K 59/80

(52) U.S. Cl. CPC H10K 59/878; H10K 59/80518

(57) ABSTRACT

A display device includes a substrate provided with a pixel including an emission area and a laser area. The display device includes a lower mirror layer over the substrate. The display device includes a first light-emitting diode provided in the emission area over the lower mirror layer. The display device includes a second light-emitting diode provided in the laser area over the lower mirror layer. The display device includes an upper mirror layer over the second light-emitting diode.

### CROSS-REFERENCE TO RELATED APPLICATIONS

The present application claims priority to Korean Patent Application No. 10-2022-0189150 filed in the Republic of Korea on Dec. 29, 2022, the entire contents of which are hereby expressly incorporated by reference into the present application.

### BACKGROUND

### Technical Field

The present disclosure relates to a display device, and more particularly, to a display device having an emission area and a laser area.

### Description of the Related Art

As one of the flat panel display devices, an electroluminescent display device has wide viewing angles as compared with a liquid crystal display device because it is self-luminous and also has advantages of a thin thickness, light weight and low power consumption since a backlight unit is not necessary.

In addition, the electroluminescent display device is driven by low voltages of direct current (DC) and has a fast response time. Further, the electroluminescent display device is strong against the external impacts and is used in a wide range of temperatures because its components are solids. In addition, the electroluminescent display device can be manufactured at low costs.

The electroluminescent display device can include a plurality of pixels, each of which has red, green, and blue sub-pixels, and can display various color images by selectively driving the red, green, and blue sub-pixels.

Recently, the electroluminescent display device has been applied to many fields, and a display device having various functions has been demanded.

### BRIEF SUMMARY

Accordingly, the present disclosure is directed to a display device that substantially obviates one or more of the problems due to limitations and disadvantages of the related art.

Various embodiments of the present disclosure provide a display device including an emission area and a laser area and capable of selectively providing information depending on circumstances.

Additional features and advantages of the present disclosure will be set forth in the description which follows, and in part will be apparent from the description, or can be learned by practice of the present disclosure. The objectives and other advantages of the present disclosure will be realized and attained by the structure particularly pointed out in the written description and claims hereof as well as the appended drawings.

To achieve these and other technical benefits, as embodied and broadly described herein, there is provided a display device includes a substrate provided with a pixel including an emission area and a laser area; a lower mirror layer over the substrate; a first light-emitting diode provided in the emission area over the lower mirror layer; a second light-emitting diode provided in the laser area over the lower mirror layer; and an upper mirror layer over the second light-emitting diode.

It is to be understood that both the foregoing general description and the following detailed description are by example and explanatory and are intended to provide further explanation of the present disclosure as claimed.

### BRIEF DESCRIPTION OF THE SEVERAL VIEWS OF THE DRAWINGS

The accompanying drawings, which are included to provide a further understanding of the present disclosure and which are incorporated in and constitute a part of this specification, illustrate an embodiment of the present disclosure and together with the description serve to explain the principles of the present disclosure.

FIG. 1 is a schematic circuit diagram of one sub-pixel of a display device according to an embodiment of the present disclosure.

FIG. 2 is a schematic cross-sectional view of a display device according to an embodiment of the present disclosure.

FIG. 3A is a schematic cross-sectional view of a lower mirror layer according to an embodiment of the present disclosure, and FIG. 3B is a schematic cross-sectional view of an upper mirror layer according to an embodiment of the present disclosure.

FIG. 4 is a schematic plan view of a display device according to a first embodiment of the present disclosure and mainly shows a bank configuration.

FIG. 5 is a schematic plan view of a display device according to the first embodiment of the present disclosure.

FIG. 6 is a schematic cross-sectional view corresponding to the line I-I′ of FIG. 4.

FIG. 7 is a schematic cross-sectional view corresponding to the line II-II′ of FIG. 4.

FIG. 8 is a graph showing a reflection band of a lower mirror layer according to an embodiment of the present disclosure.

FIG. 9 is a schematic plan view of a display device according to a second embodiment of the present disclosure.

FIG. 10 is a schematic plan view of a display device according to the second embodiment of the present disclosure.

FIG. 11 is a schematic plan view of a display device according to a third embodiment of the present disclosure.

FIG. 12 is a schematic plan view of a display device according to the third embodiment of the present disclosure.

FIG. 13 is a schematic cross-sectional view corresponding to the line III-III′ of FIG. 11.

### DETAILED DESCRIPTION

Reference will now be made in detail to exemplary embodiments of the present disclosure, examples of which may be illustrated in the accompanying drawings. All the components of each display device according to all embodiments of the present disclosure are operatively coupled and configured. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals designate like elements throughout. Names of the respective elements used in the following explanations may be selected only for convenience of writing the specification and may be thus different from those used in actual products.

Advantages and features of the present disclosure, and implementation methods thereof will be clarified through the following example embodiments described with reference to the accompanying drawings. The present disclosure may however, be embodied in different forms and should not be construed as limited to the example embodiments set forth herein. Rather, these example embodiments may be provided so that this disclosure may be sufficiently thorough and complete, to assist those skilled in the art to fully understand the scope of the present disclosure.

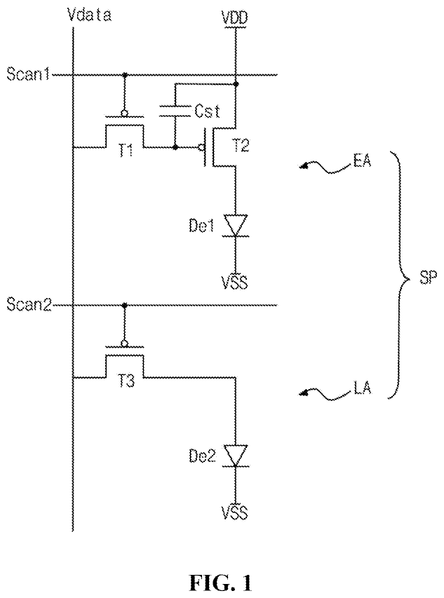

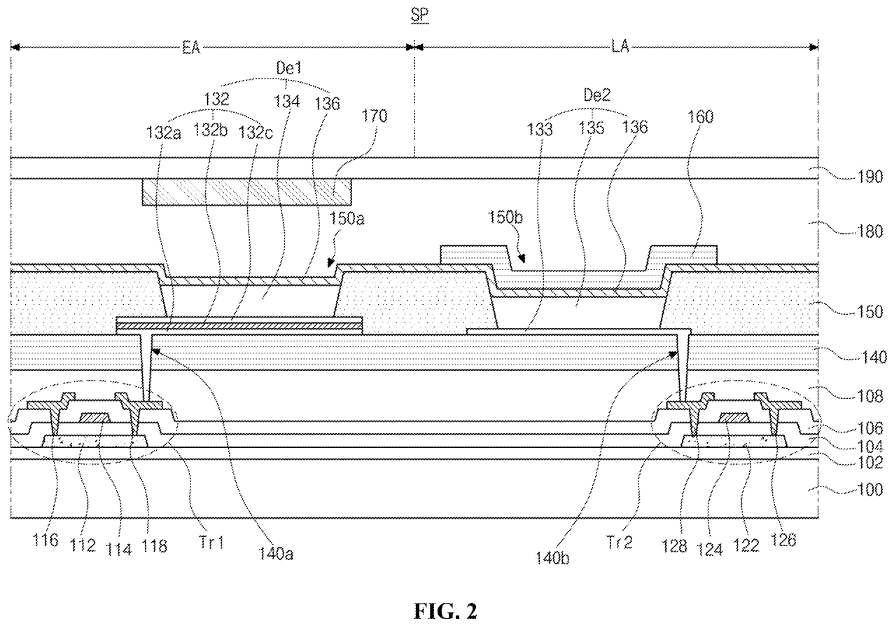

A display device according to embodiments of the present disclosure can display an image using an electroluminescent display device. The display device using an electroluminescent display device can include a plurality of pixels to display an image, and each of the plurality of pixels can include a plurality of sub-pixels. Each sub-pixel can have a configuration shown in FIG. 1 and FIG. 2.

FIG. 1 is a schematic circuit diagram of one sub-pixel of a display device according to an embodiment of the present disclosure.

In FIG. 1, the sub-pixel SP of the display device according to the embodiment of the present disclosure can include an emission area EA and a laser area LA. The emission area EA can include a first transistor T1, a second transistor T2, a storage capacitor Cst, and a first light-emitting diode De1, and the laser area LA can include a third transistor T3 and a second light-emitting diode De2. In one or more embodiments, the term “laser area” can also be replaceably used with the term “light source emission area.” In some embodiments, the laser area is an area configured to emit laser. For instance, when a specific emergency situation occurs such as a fire that is difficult to secure visibility, light emitted from a light-emitting diode in the laser area can be reflected between two dielectric mirrors and output light as a laser beam. Since the laser beam is coherent, the visibility can be maximized, and in the event of a fire, a visible distance can be easily secured, thereby helping to save lives. Further, the information provided through the laser area can be an image or a letter. However, the present disclosure is not limited to a light emitting source such as a laser and therefore, may also be referred to as the light source emission area. The light source emission area is an area configured to emit light such as a focused light source such as a laser. However, the source of the light is not limited to a laser and any other light source can be used.

Here, the first, second, and third transistors T1, T2, and T3 can be p-type transistors. However, embodiments of the present disclosure are not limited thereto. Alternatively, the first, second, and third transistors T1, T2, and T3 can be n-type transistors.

Specifically, in the emission area EA, a first gate line supplying a first gate signal Scan1 and a data line supplying a data signal Vdata can cross each other, and the first transistor T1 can be disposed at a crossing point of the first gate line and the data line. A gate of the first transistor T1 can be connected to the first gate line to receive the first gate signal Scan1. A source of the first transistor T1 can be connected to the data line to receive the data signal Vdata. The first transistor T1 can be a switching transistor.

Additionally, in the emission area EA, a gate of the second transistor T2 can be connected to a drain of the first transistor T1 and a first capacitor electrode of the storage capacitor Cst. A source of the second transistor T2 can be connected to a high potential line supplying a high potential voltage VDD and a second capacitor electrode of the storage capacitor Cst. A drain of the second transistor T2 can be connected to an anode of the first light-emitting diode De1. The second transistor T2 can be a driving transistor.

Here, source and drain locations of each of the first, second, and third transistors T1, T2, and T3 are not limited thereto, and the locations can be interchanged or varied.

A cathode of the first light-emitting diode De1 can be connected to a low potential line supplying a low potential voltage VSS. Alternatively, the cathode of the first light-emitting diode De1 can be connected to a ground voltage.

During an emission period of one frame, the first transistor T1 can be switched according to the first gate signal Scan1 transmitted through the first gate line to thereby provide the gate of the second transistor T2 with the data signal Vdata transmitted through the data line. The second transistor T2 can be switched according to the data signal Vdata to thereby control a current of the first light-emitting diode De1.

In this case, the storage capacitor Cst can maintain charges corresponding to the data signal Vdata for one frame. Accordingly, even if the first transistor T1 is turned off, the storage capacitor Cst can allow the amount of the current flowing through the first light-emitting diode De1 to be constant and the gray level shown by the first light-emitting diode De1 to be maintained until a next frame.

Meanwhile, in the emission area EA, at least one transistor and/or at least one capacitor can be further provided in addition to the first and second transistors T1 and T2 in order to compensate the change of the mobility and/or threshold voltage of the second transistor T2 driven for a relatively long time.

Next, in the laser area LA, a second gate line supplying a second gate signal Scan2 and the data line can cross each other, and the third transistor T3 can be disposed at a crossing point of the second gate line and the data line. A gate of the third transistor T3 can be connected to the second gate line to receive the second gate signal Scan2, and a source of the third transistor T3 can be connected to the data line to receive the data signal Vdata. The third transistor T3 can be a switching transistor.

An anode of the second light-emitting diode De2 can be connected to a drain of the third transistor T3, and a cathode of the second light-emitting diode De2 can be connected to the low potential line supplying the low potential voltage VSS similarly to the cathode of the first light-emitting diode De1. Alternatively, when the cathode of the first light-emitting diode De1 is connected to the ground voltage, the cathode of the second light-emitting diode De2 can also be connected to the ground voltage.

The third transistor T3 can be switched according to the second gate signal Scan2 transmitted through the second gate line to thereby provide the second light-emitting diode De2 with the data signal Vdata transmitted through the data line, so that the second light-emitting diode De2 can emit light.

The second light-emitting diode De2 of the laser area LA can be disposed between two dielectric mirrors, thereby forming a resonance structure.

Accordingly, when a specific situation occurs, for example, an emergency situation such as a fire that is difficult to secure visibility, light emitted from the second light-emitting diode De2 can be reflected between the two dielectric mirrors and output as a laser beam. Since the laser beam is coherent, the visibility can be maximized, and in the event of a fire, a visible distance can be easily secured, thereby helping to save lives.

A cross-sectional structure of the display device including the emission area and the laser area according to the embodiment of the present disclosure will be described in detail with reference to FIG. 2.

FIG. 2 is a schematic cross-sectional view of a display device according to an embodiment of the present disclosure and shows one sub-pixel. Here, the display device according to the embodiment of the present disclosure can use a top emission type electroluminescent display device as an example.

As shown in FIG. 2, the display device according to the embodiment of the present disclosure can include a substrate 100 provided with a sub-pixel SP including an emission area EA and a laser area LA, first and second thin film transistors Tr1 and Tr2, first and second light-emitting diodes De1 and De2, a lower mirror layer 140, an upper mirror layer 160, a color filter 170, an encapsulation layer 180, and a counter substrate 190.

More particularly, the sub-pixel SP provided over the substrate 100 can include the emission area EA and the laser area LA. The substrate 100 can be a glass substrate or a plastic substrate. For example, polyimide can be used for the plastic substrate, but the embodiments of the present disclosure are not limited thereto.

A buffer layer 102 can be formed over the substrate 100. The buffer layer 102 can be disposed over substantially an entire surface of the substrate 100. The buffer layer 102 can be formed of an inorganic insulating material such as silicon oxide (SiOₓ) or silicon nitride (SiNx) and can be formed as a single layer or multi layers.

A first semiconductor layer 112 can be patterned and formed in the emission area EA over the buffer layer 102, and a second semiconductor layer 122 can be patterned and formed in the laser area LA over the buffer layer 102.

The first and second semiconductor layers 112 and 122 can be formed of an oxide semiconductor material. In this case, a light-blocking pattern can be formed under each of the first and second semiconductor layers 112 and 122. The light-blocking pattern can block light incident on the first and second semiconductor layers 112 and 122 and prevent the first and second semiconductor layers 112 and 122 from deteriorating due to the light.

Alternatively, the first and second semiconductor layers 112 and 122 can be formed of polycrystalline silicon, and in this case, both ends of each of the first and second semiconductor layers 112 and 122 can be doped with impurities.

A gate insulation layer 104 of an insulating material can be formed over the first and second semiconductor layers 112 and 122. The gate insulation layer 104 can be disposed over substantially the entire surface of the substrate 100. The gate insulation layer 104 can be formed of an inorganic insulating material such as silicon oxide (SiOx) or silicon nitride (SiNx).

When the first and second semiconductor layers 112 and 122 are made of an oxide semiconductor material, the gate insulation layer 104 can be formed of silicon oxide (SiOx). Alternatively, when the first and second semiconductor layers 112 and 122 are made of polycrystalline silicon, the gate insulation layer 104 can be formed of silicon oxide (SiOx) or silicon nitride (SiNx).

First and second gate electrodes 114 and 124 of a conductive material such as metal can be formed over the gate insulation layer 104 to correspond to the first and second semiconductor layers 112 and 122, respectively.

The first and second gate electrodes 114 and 124 can be formed of at least one of aluminum (Al), copper (Cu), molybdenum (Mo), titanium (Ti), chromium (Cr), nickel (Ni), tungsten (W) or an alloy thereof and can have a single-layered structure or a multi-layered structure. For example, the first and second gate electrodes 114 and 124 can have a double-layered structure including a lower layer of a molybdenum-titanium alloy (MoTi) and an upper layer of copper (Cu), and the upper layer can have a thicker thickness than the lower layer. However, the embodiments of the present disclosure are not limited thereto.

In addition, first and second gate lines can be further formed of the same material and on the same layer as the first and second gate electrodes 114 and 124 over the gate insulation layer 104. The first and second gate lines can be connected to the first and second gate electrodes 114 and 124, respectively, and can extend in a first direction.

Meanwhile, in the embodiment of the present disclosure, although the gate insulation layer 104 is disposed over substantially the entire surface of the substrate 100 as an example, the gate insulation layer 104 can be patterned to have substantially the same shape as the first and second gate electrodes 114 and 124.

A passivation layer 106 made of an insulating material can be formed over the first and second gate electrodes 114 and 124 over substantially the entire surface of the substrate 100. The passivation layer 106 can be formed of an inorganic insulating material such as silicon oxide (SiOx) or silicon nitride (SiNx). Alternatively, the passivation layer 106 can be formed of an organic insulating material such as photosensitive acrylic polymer (photo acryl) or benzocyclobutene.

The passivation layer 106 can have contact holes exposing both ends of each of the first and second semiconductor layers 112 and 122. Here, the contact holes can be formed in the gate insulation layer 104.

First source and first drain electrodes 116 and 118 and second source and second drain electrodes 126 and 128 made of a conductive material such as metal can be formed over the passivation layer 106. The first source and first drain electrodes 116 and 118 can be disposed in the emission area EA, and the second source and second drain electrodes 126 and 128 can be disposed in the laser area LA. In addition, a data line and a power line extending in a second direction perpendicular to the first direction can be formed over the passivation layer 106.

The first source and first drain electrodes 116 and 118 and the second source and second drain electrodes 126 and 128 can be formed of at least one of aluminum (Al), copper (Cu), molybdenum (Mo), titanium (Ti), chromium (Cr), nickel (Ni), tungsten (W) or an alloy thereof and can have a single-layered structure or a multi-layered structure. For example, the first source and first drain electrodes 116 and 118 and the second source and second drain electrodes 126 and 128 can have a double-layered structure including a lower layer of a molybdenum-titanium alloy (MoTi) and an upper layer of copper (Cu), and the upper layer can have a thicker thickness than the lower layer. Alternatively, the first source and first drain electrodes 116 and 118 and the second source and second drain electrodes 126 and 128 can have a triple-layered structure.

The first source and first drain electrodes 116 and 118 can contact the both ends of the first semiconductor layer 112 through the contact holes of the passivation layer 106, and the second source and second drain electrodes 126 and 128 can contact the both ends of the second semiconductor layer 122 through the contact holes of the passivation layer 106.

The first semiconductor layer 112, the first gate electrode 114, and the first source and first drain electrodes 116 and 118 can form the first thin film transistor Tr1. The second semiconductor layer 122, the second gate electrode 124, and the second source and second drain electrodes 126 and 128 can form the second thin film transistor Tr2.

The first thin film transistor Tr1 can be the second transistor T2 of FIG. 1, and the second thin film transistor Tr2 can be the third transistor T3 of FIG. 1.

In addition, one or more thin film transistors having the same structure as the first thin film transistor Tr1 can be further formed in the emission area EA of each sub-pixel SP over the substrate 100, but the embodiments of the present disclosure are not limited thereto.

An overcoat layer 108 of an insulating material can be formed over the first source and first drain electrodes 116 and 118 and the second source and second drain electrodes 126 and 128 over substantially the entire surface of the substrate 100. The overcoat layer 108 can be formed of an organic insulating material such as photosensitive acrylic polymer (photo acryl) or benzocyclobutene. The overcoat layer 108 can eliminate level differences due to under layers and have a substantially flat top surface.

Meanwhile, an insulation layer of an inorganic insulating material such as silicon oxide (SiOx) or silicon nitride (SiNx) can be further formed under the overcoat layer 108, that is, between the first and second thin film transistors Tr1 and Tr2 and the overcoat layer 108.

The lower mirror layer 140 can be formed over the overcoat layer 108 over substantially the entire surface of the substrate 100. The lower mirror layer 140 can have a structure in which two layers having different refractive indexes are alternately stacked, and this will be described in detail later.

The lower mirror layer 140 can have first and second contact holes 140a and 140b together with the overcoat layer 108. The first and second contact holes 140a and 140b can expose the first and second drain electrodes 118 and 128, respectively.

First and second pixel electrodes 132 and 133 can be formed over the lower mirror layer 140. The first pixel electrode 132 can be disposed in the emission area EA and be in contact with the first drain electrode 118 through the first contact hole 140a. The second pixel electrode 133 can be disposed in the laser area LA and be in contact with the second drain electrode 128 through the second contact hole 140b.

The first and second pixel electrodes 132 and 133 can be formed of a conductive material having relatively high work function. The first and second pixel electrodes 132 and 133 can include a transparent electrode. For example, the transparent electrode can be formed of a transparent conductive material such as indium tin oxide (ITO) or indium zinc oxide (IZO).

Here, the first pixel electrode 132 can reflect light, and the second pixel electrode 133 can transmit light. The first pixel electrode 132 can include the transparent electrode and a reflective electrode, and the second pixel electrode 133 can include the transparent electrode and may not include a reflective electrode.

Accordingly, the first pixel electrode 132 can have a multi-layered structure. For example, the first pixel electrode 132 can has a triple-layered structure including a first layer 132a, a second layer 132b, and a third layer 132c sequentially layered. Here, the first layer 132a and the third layer 132c can be the transparent electrode, and the second layer 132b can be the reflective electrode. Each of the first layer 132a and the third layer 132c can be formed of a transparent conductive material such as indium tin oxide (ITO) or indium zinc oxide (IZO). In addition, the second layer 132b can be formed of a metal material having relatively high reflectance such as silver (Ag), aluminum (Al), molybdenum (Mo), or an alloy thereof. Here, silver alloy (Ag alloy) can be silver-palladium-copper (Ag—Pd—Cu: APC).

Alternatively, the first pixel electrode 132 can have a double-layered structure in which the transparent electrode is disposed over the reflective electrode.

Meanwhile, the second pixel electrode 133 can have a single-layered structure. For example, the second pixel electrode 133 can have one transparent electrode formed of a transparent conductive material such as ITO or IZO.

A bank 150 of an insulating material can be formed on the first and second pixel electrodes 132 and 133. The bank 150 can overlap and cover edges of each of the first and second pixel electrodes 132 and 133. The bank 150 can have first and second openings 150a and 150b exposing the first and second pixel electrodes 132 and 133, respectively.

The bank 150 can be formed of an organic material such as acrylic resin, epoxy resin, phenol resin, polyamide resin, or polyimide resin. However, the embodiments of the present disclosure are not limited thereto. Alternatively, the bank 150 can be formed of an inorganic insulating material such as silicon oxide (SiOx) or silicon nitride (SiNx).

The bank 150 can overlap the first and second thin film transistors Tr1 and Tr2. Namely, the first and second thin film transistors Tr1 and Tr2 can be disposed under the bank 150. However, the embodiments of the present disclosure are not limited thereto. Alternatively, the first thin film transistor Tr1 can be spaced apart from the bank 150 and be disposed to correspond to the first opening 150a.

Next, first and second light-emitting layers 134 and 135 can be formed over the first and second pixel electrodes 132 and 133 exposed through the first and second openings 150a and 150b of the bank 150, respectively.

The first light-emitting layer 134 and the second light-emitting layer 135 can have the same configuration and be formed of the same material. Here, although the first light-emitting layer 134 and the second light-emitting layer 135 are shown as being separated from each other, the embodiments of the present disclosure are not limited thereto. Alternatively, the first light-emitting layer 134 and the second light-emitting layer 135 can be connected to each other to thereby form one body. In this case, a light-emitting layer can be separated for each sub-pixel SP, or one light-emitting layer can be formed over substantially the entire surface of the substrate 100.

The first light-emitting layer 134 and the second light-emitting layer 135 can emit white light. However, the embodiments of the present disclosure are not limited thereto. Alternatively, the first light-emitting layer 134 and the second light-emitting layer 135 can emit at least one of red, green, and blue light.

Although not shown in the figure, each of the first light-emitting layer 134 and the second light-emitting layer 135 can include at least one hole auxiliary layer, at least one light-emitting material layer, and at least one electron auxiliary layer constituting one light-emitting unit. The light-emitting material layer can be formed of any one of red, green, and blue luminescent materials. The luminescent material can be an organic luminescent material such as a phosphorescent compound or a fluorescent compound or can be an inorganic luminescent material such as a quantum dot.

The hole auxiliary layer can include at least one of a hole injection layer (HIL) and a hole transport layer (HTL). The electron auxiliary layer can include at least one of an electron injection layer (EIL) and an electron transport layer (ETL).

The first light-emitting layer 134 and the second light-emitting layer 135 can be formed through a deposition process such as a thermal evaporation method. In this case, in order to pattern the first light-emitting layer 134 and the second light-emitting layer 135, a fine metal mask (FMM) can be used. However, the embodiments of the present disclosure are not limited thereto. Alternatively, the first light-emitting layer 134 and the second light-emitting layer 135 can be formed through a solution process such as a spin coating method, an ink jet printing method, or a screen printing method.

A common electrode 136 can be formed over the first light-emitting layer 134 and the second light-emitting layer 135 over substantially the entire surface of the substrate 100. That is, the common electrode 136 can be formed not only in the emission area EA but also in the laser area LA.

The common electrode 136 can be in contact with top and side surfaces of the bank 150. Alternatively, when the first and second light-emitting layers 134 and 135 are disposed over substantially the entire surface of the substrate 100, the common electrode 136 can be in contact with the first and second light-emitting layers 134 and 135 over the bank 150.

The common electrode 136 can be formed of a conductive material having a relatively low work function. For example, the common electrode 136 can be formed of aluminum (Al), magnesium (Mg), silver (Ag), gold (Au), or an alloy thereof. In this case, the common electrode 136 can have a relatively thin thickness such that light from the first and second light-emitting layers 134 and 135 can be transmitted therethrough. For example, the common electrode 136 can have the thickness of 5 nm to 10 nm, but the embodiments of the present disclosure are not limited thereto.

Alternatively, the common electrode 136 can be formed of a transparent conductive material such as indium gallium oxide (IGO).

The first pixel electrode 132, the first light-emitting layer 134, and the common electrode 136 of the emission area EA constitute the first light-emitting diode De1, and the second pixel electrode 133, the second light-emitting layer 135, and the common electrode 136 of the laser area LA constitute the second light-emitting diode De2.

Next, the upper mirror layer 160 can be disposed over the common electrode 136 in the laser area LA. That is, the upper mirror layer 160 can be disposed over the second light-emitting diode De2. The upper mirror layer 160 may not be provided in the emission area EA.

The upper mirror layer 160 can have a structure in which two layers having different refractive indexes are alternately stacked, and this will be described in detail later.

An encapsulation layer 180 can be provided over the common electrode 136 of the emission area EA and the upper mirror layer 160 of the laser area LA over substantially the entire surface of the substrate 100.

The encapsulation layer 180 can be formed as a single layer of an inorganic insulating material or an organic insulating material or formed as multiple layers of an inorganic insulating material and an organic insulating material. When the encapsulation layer 180 is formed as multiple layers, the encapsulation layer 180 can include an organic material layer and an inorganic material layer or an inorganic material layer, an organic material layer, and an inorganic material layer sequentially stacked.

For example, the encapsulation layer 180 can include an inorganic insulating material such as silicon oxide (SiOx) or silicon nitride (SiNx) or an organic insulating material such as acrylic resin or epoxy resin. However, the embodiments of the present disclosure are not limited thereto.

In addition, although not shown in the figure, a capping layer and a protective layer can be sequentially provided between the encapsulation layer 180 and the common electrode 136 and between the encapsulation layer 180 and the upper mirror layer 160 over substantially the entire surface of the substrate 100.

The capping layer can be formed of an insulating material having a relatively high refractive index. The wavelength of light traveling along the capping layer can be amplified by surface plasma resonance, and thus the intensity of the peak can be increased, thereby improving the light efficiency in the top emission type electroluminescent display device. For example, the capping layer can be formed as a single layer of an organic layer or an inorganic layer or formed as organic/inorganic stacked layers.

Further, the protective layer can block moisture or oxygen introduced from the outside together with the encapsulation layer 180, thereby protecting the first and second light-emitting diodes De1 and De2. The protective layer can be formed of an inorganic insulating material such as aluminum oxide (AlOx), silicon oxide (SiOx), or silicon nitride (SiNx), but the embodiments of the present disclosure are not limited thereto.

The counter substrate 190 can be disposed over the encapsulation layer 180. The counter substrate 190 can be transparent and have a thinner thickness than the substrate 100.

The counter substrate 190 can be a glass substrate or a plastic substrate. For example, polyimide can be used for the plastic substrate, but the embodiments of the present disclosure are not limited thereto.

Meanwhile, the color filter 170 can be provided in the emission area EA between the encapsulation layer 180 and the counter substrate 190. The color filter 170 can be one of red, green, and blue color filters. The color filter 170 can be provided on one surface of the counter substrate 190, that is, a surface facing the first light-emitting diode De1.

Accordingly, the substrate 100 provided with the encapsulation layer 180 can be attached to the counter substrate 190 provided with the color filter 170 to thereby constitute the display device.

As such, in the display device according to the embodiment of the present disclosure, each sub-pixel SP can have the emission area EA and the laser area LA. The first light-emitting diode De1 and the second light-emitting diode De2 can be provided in the emission area EA and the laser area LA, respectively, and the lower mirror layer 140 and the upper mirror layer 160 can be provided in the laser area LA. Accordingly, an image can be displayed through the emission area EA at ordinary times, and information can be provided by generating a laser beam through the laser area LA in an emergency situation, thereby helping to save lives. In this case, the information provided through the laser area LA can be an image or a letter.

The laser area LA and the emission area EA can be formed together, and can be implemented through existing processes, so that manufacturing processes can be optimized and producing energy can be reduced.

In addition, the top emission type display device can have a wider effective emission area than a bottom emission type display device of the same size, to thereby improve luminance and reduce power consumption.

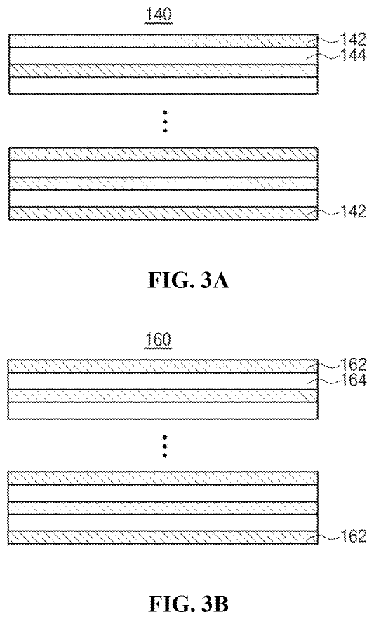

The structures of the lower mirror layer 140 and the upper mirror layer 160 of the laser area LA will be described in detail with reference to FIGS. 3A and 3B.

FIG. 3A is a schematic cross-sectional view of a lower mirror layer according to an embodiment of the present disclosure, and FIG. 3B is a schematic cross-sectional view of an upper mirror layer according to an embodiment of the present disclosure.

In FIG. 3A, the lower mirror layer 140 can include a plurality of first lower refractive index layers 142 and a plurality of second lower refractive index layers 144, which have different refractive indexes and are alternately stacked.

The first lower refractive index layer 142 can be a high refractive index layer having a relatively high refractive index, and the second lower refractive index layer 144 can be a low refractive index layer having a relatively low refractive index. That is, the first lower refractive index layer 142 can have the higher refractive index than the second lower refractive index layer 144.

For example, the first lower refractive index layer 142 can be formed of TiO₂, Ta₂O₅, ZrO₂, or ZnS, and the second lower refractive index layer 144 can be formed of SiO₂, MgF₂, Y₂O₃, or Al₂O₃.

In addition, the second lower refractive index layer 144 can have a thicker thickness than the first lower refractive index layer 142.

One first lower refractive index layer 142 and one second lower refractive index layer 144 can constitute one set, and the lower mirror layer 140 can include ten to twenty sets.

The lower mirror layer 140 can include the odd number of layers. In this case, the number of the first lower refractive index layers 142 can be greater than the number of the second lower refractive index layers 144, and the uppermost layer and the lowermost layer of the lower mirror layer 140 can be the first lower refractive index layers 142.

However, the embodiments of the present disclosure are not limited thereto. Alternatively, the lower mirror layer 140 can include the even number of layers, and the number of the first lower refractive index layers 142 can be equal to the number of the second lower refractive index layers 144.

Next, in FIG. 3B, the upper mirror layer 160 can include a plurality of first upper refractive index layers 162 and a plurality of second upper refractive index layers 164, which have different refractive indexes and are alternately stacked.

The first upper refractive index layer 162 can be a high refractive index layer having a relatively high refractive index, and the second upper refractive index layer 164 can be a low refractive index layer having a relatively low refractive index. That is, the first upper refractive index layer 162 can have the higher refractive index than the second upper refractive index layer 164.

For example, the first upper refractive index layer 162 can be formed of TiO₂, Ta₂O₅, ZrO₂, or ZnS, and the second upper refractive index layer 164 can be formed of SiO₂, MgF₂, Y₂O₃, or Al₂O₃.

In addition, the second upper refractive index layer 164 can have a thicker thickness than the first upper refractive index layer 162.

One first upper refractive index layer 162 and one second upper refractive index layer 164 can constitute one set, and the upper mirror layer 160 can include ten to twenty sets.

The upper mirror layer 160 can include the odd number of layers. In this case, the number of the first upper refractive index layers 162 can be greater than the number of the second upper refractive index layers 164, and the uppermost layer and the lowermost layer of the upper mirror layer 160 can be the first upper refractive index layers 162.

However, the embodiments of the present disclosure are not limited thereto. Alternatively, the upper mirror layer 160 can include the even number of layers, and the number of the first upper refractive index layers 162 can be equal to the number of the second upper refractive index layers 164.

The lower mirror layer 140, the upper mirror layer 160, and the second light-emitting diode De2 therebetween can constitute a laser element. That is, the lower mirror layer 140 and the upper mirror layer 160 can form a resonator and reflect light emitted from the second light-emitting diode De2 to output a laser beam.

In this case, the closer the reflectances of the lower mirror layer 140 and the upper mirror layer 160 are to 100%, the easier it is for laser oscillation.

The lower mirror layer 140 and the upper mirror layer 160 can have different reflectances and thicknesses. Specifically, the reflectance of the lower mirror layer 140 can be higher than the reflectance of the upper mirror layer 160 and the thickness of the lower mirror layer 140 can be thicker than the thickness of the upper mirror layer 160.

In addition, a difference between the refractive indexes of the first lower refractive index layer 142 and the second lower refractive index layer 144 of the lower mirror layer 140 can be greater than a difference between the refractive indexes of the first upper refractive index layer 162 and the second upper refractive index layer 164 of the upper mirror layer 160.

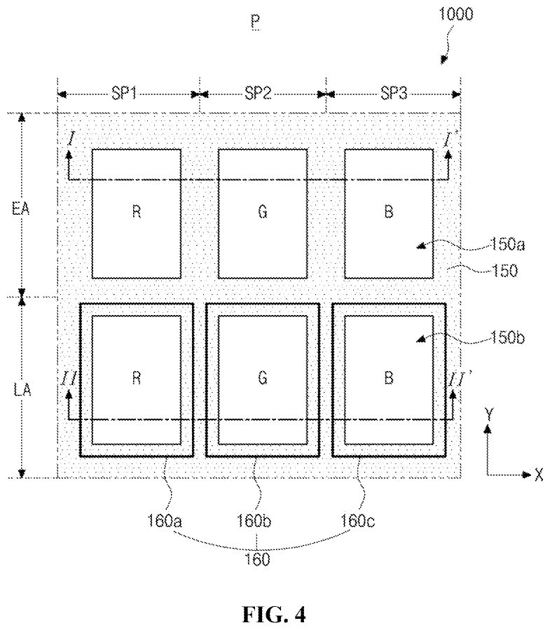

A pixel arrangement structure of the display device including the emission area and the laser area according to the embodiment of the present disclosure will be described in detail with reference to FIG. 4.

FIG. 4 is a schematic plan view of a display device according to a first embodiment of the present disclosure and mainly shows a bank configuration. FIG. 4 will be described with reference to FIG. 2 together.

As shown in FIG. 4, in the display device 1000 according to the first embodiment of the present disclosure, a pixel P can include at least one emission area EA and at least one laser area LA. In this case, the pixel P can include three emission areas EA and three laser areas LA.

More particularly, the pixel P can include first, second, and third sub-pixels SP1, SP2, and SP3 sequentially arranged along a first direction, which is an X direction. For example, the first, second, and third sub-pixels SP1, SP2, and SP3 can be red, green, and blue sub-pixels R, G, and B. Each of the first, second, and third sub-pixels SP1, SP2, and SP3 can include the emission area EA and the laser area LA arranged along a second direction, which is a Y direction.

The emission areas EA of the first, second, and third sub-pixels SP1, SP2, and SP3 can have the same size. However, the embodiments of the present disclosure are not limited thereto. Alternatively, the emission areas EA of the first, second, and third sub-pixels SP1, SP2, and SP3 can have different sizes.

Further, in each of the first, second, and third sub-pixels SP1, SP2, and SP3, the emission area EA and the laser area LA can have the same size. Alternatively, the size of the laser area LA can be smaller than the size of the emission area EA.

The emission areas EA and the laser areas LA of the first, second, and third sub-pixels SP1, SP2, and SP3 can be defined by a bank 150. The bank 150 can be disposed between the emission areas EA, between the laser areas LA, and between the emission area EA and the laser area LA of the adjacent first, second, and third sub-pixels SP1, SP2, and SP3. In addition, the bank 150 can also be disposed between the emission areas EA and between the laser areas LA of the adjacent pixels P.

The bank 150 can have a first opening 150a corresponding to the emission area EA of each of the first, second, and third sub-pixels SP1, SP2, and SP3 and a second opening 150b corresponding to the laser area LA of each of the first, second, and third sub-pixels SP1, SP2, and SP3. That is, the bank 150 can have three first openings 150a and three second openings 150b for one pixel P.

The first and second openings 150a and 150b can define an effective emission area. The first and second openings 150a and 150b are shown as having a rectangular shape with angled corners, but the embodiments of the present disclosure are not limited thereto. Alternatively, the first and second openings 150a and 150b can have various shapes such as a rectangular shape with curved corners, polygonal shapes other than a rectangular shape, or an oval shape.

As described above, each of the first, second, and third sub-pixels SP1, SP2, and SP3 can include the first light-emitting diode De1 in the emission area EA and the second light-emitting diode De2 in the laser area LA. Accordingly, the pixel P can include three first light-emitting diodes De1 and three second light-emitting diodes De2.

In addition, each of the first, second, and third sub-pixels SP1, SP2, and SP3 can include the lower mirror layer 140 and the upper mirror layer 160 in the laser area LA. Here, the lower mirror layer 140 can also be provided in the emission areas EA of the first, second, and third sub-pixels SP1, SP2, and SP3. On the other hand, the upper mirror layer 160 can be provided only in the laser areas LA of the first, second, and third sub-pixels SP1, SP2, and SP3 and can include first, second, and third mirror layers 160a, 160b, and 160c corresponding to the first, second, and third sub-pixels SP1, SP2, and SP3, respectively.

The laser areas LA of the first, second, and third sub-pixels SP1, SP2, and SP3 can generate red, green, and blue laser beams, respectively.

Meanwhile, although not shown in the figure, the color filter 170 of FIG. 2 can be provided in the emission areas EA of the first, second, and third sub-pixels SP1, SP2, and SP3, and the color filter 170 can include first, second, and third color filters corresponding to the first, second, and third sub-pixels SP1, SP2, and SP3, respectively.

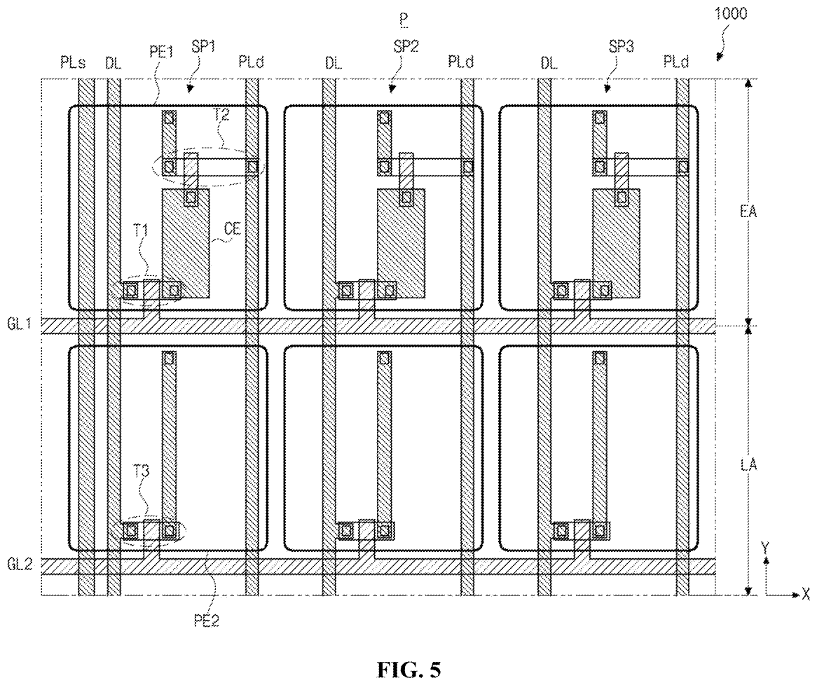

A planar structure of the display device 1000 according to the first embodiment of the present disclosure will be described with reference to FIG. 5.

FIG. 5 is a schematic plan view of a display device according to the first embodiment of the present disclosure and shows one pixel. FIG. 5 will be described with reference to FIG. 1 together.

As shown in FIG. 5, in the display device 1000 according to the first embodiment of the present disclosure, a first gate line GL1 and a second gate line GL2 can extend in a first direction, which is an X direction, and three data lines DL and three first power lines PLd can extend in a second direction, which is a Y direction. The first gate line GL1 and the second gate line GL2 can cross the data lines DL and the first power lines PLd to define a pixel P including first, second, and third sub-pixels SP1, SP2, and SP3. The three data lines DL and the three first power lines PLd can be alternately arranged along the first direction.

Each of the first, second, and third sub-pixels SP1, SP2, and SP3 can include an emission area EA and a laser area LA. The emission area EA and the laser area LA can be arranged along the second direction.

In addition, a second power line PLs can extend in the second direction and can cross the first and second gate lines GL1 and GL2. One second power line PLs can be provided for one pixel P. For example, the second power line PLs can be provided on a left side of the first sub-pixel SP1.

Here, the first power line PLd can be a high potential line supplying the high potential voltage VDD of FIG. 1, and the second power line PLs can be a low potential line supplying the low potential voltage VSS of FIG. 1.

A first transistor T1, a second transistor T2, a capacitor electrode CE, and a first pixel electrode PE1 can be provided in the emission area EA of each sub-pixel SP1, SP2, and SP3, and a third transistor T3 and a second pixel electrode PE2 can be provided in the laser area LA of each sub-pixel SP1, SP2, and SP3.

The first transistor T1 can be disposed at a crossing point of each data line DL and the first gate line GL1 and be connected to each data line DL and the first gate line GL1. In addition, the first transistor T1 can be connected to the capacitor electrode CE.

The second transistor T2 can be connected to each first power line PLd and the first pixel electrode PE1. In addition, the second transistor T2 can be connected to the capacitor electrode CE.

The capacitor electrode CE can be connected to the first and second transistors T1 and T2 and overlap the first pixel electrode PE1, thereby forming a storage capacitor. Alternatively, the capacitor electrode CE can overlap a separate electrode connected to the first pixel electrode PE1, thereby forming a storage capacitor.

Next, the third transistor T3 can be disposed at a crossing point of each data line DL and the second gate line GL2 and be connected to each data line DL and the second gate line GL2. In addition, the third transistor T3 can be connected to the second pixel electrode PE2.

Accordingly, in the display device 1000 according to the first embodiment of the present disclosure, one pixel P can include three first pixel electrodes PE1 and three second pixel electrodes PE2. The first transistor T1 and the third transistor T3 can be connected to the different first and second gate lines GL1 and GL2 and connected to the same data line DL.

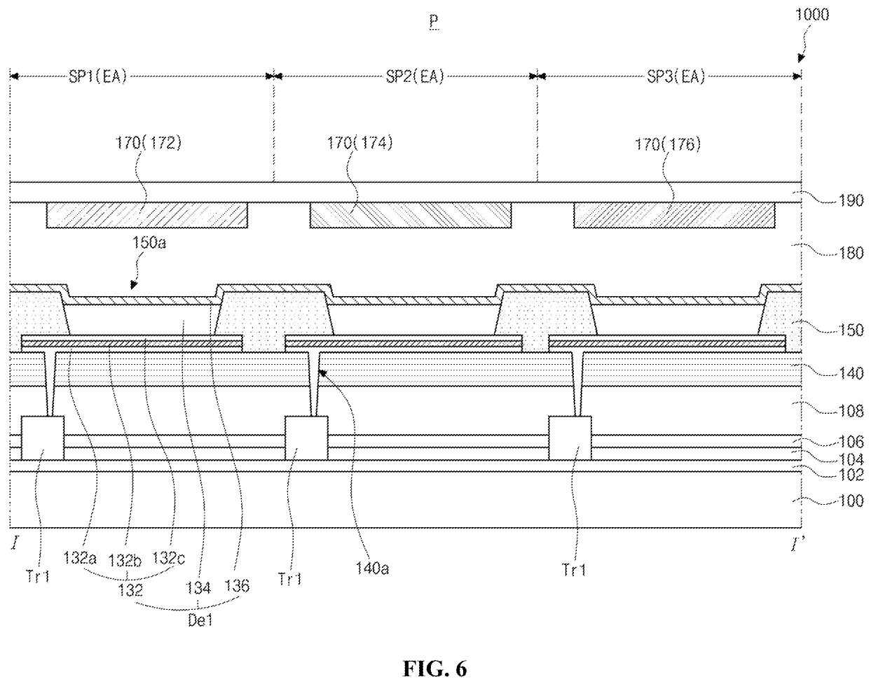

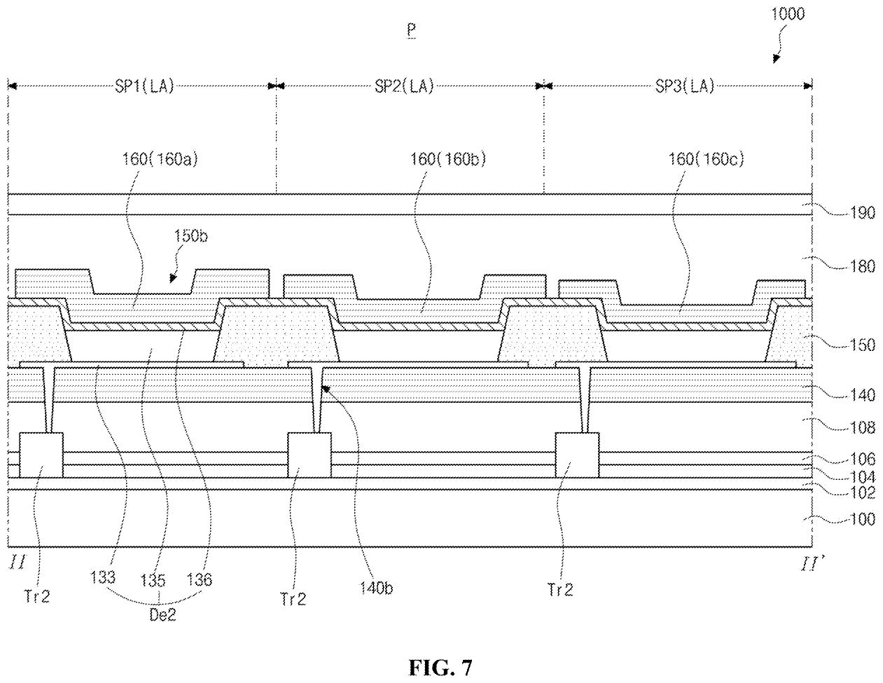

A cross-sectional structure of the emission area EA and the laser area LA of the display device 1000 according to the first embodiment of the present disclosure will be described in detail with reference to FIG. 6 and FIG. 7.

FIG. 6 and FIG. 7 are schematic cross-sectional views of the display device according to the first embodiment of the present disclosure. FIG. 6 shows a cross-section corresponding to the line I-I′ of FIG. 4, and FIG. 7 shows a cross-section corresponding to the line II-II′ of FIG. 4.

In FIG. 6 and FIG. 7, the display device 1000 according to the first embodiment of the present disclosure can include at least one pixel P provided over a substrate 100, and the pixel P can include first, second, and third sub-pixels SP1, SP2, and SP3. Each of the first, second, and third sub-pixels SP1, SP2, and SP3 can have an emission area EA and a laser area LA.

Specifically, a buffer layer 102 can be provided over the substrate 100. A first thin film transistor Tr1, a second thin film transistor Tr2, and a gate insulation layer 104, a passivation layer 106, and an overcoat layer 108 sequentially stacked can be provided over the buffer layer 102.

The first thin film transistor Tr1 can be disposed in the emission area EA of each of the first, second, and third sub-pixels SP1, SP2, and SP3, and the second thin film transistor Tr2 can be disposed in the laser area LA of each of the first, second, and third sub-pixels SP1, SP2, and SP3. The first and second thin film transistors Tr1 and Tr2 can have the same configurations as the first and second thin film transistors Tr1 and Tr2 shown in FIG. 2. That is, the first thin film transistor Tr1 can include the first semiconductor layer 112, the first gate electrode 114, the first source electrode 116 and the first drain electrode 118 shown in FIG. 2. The second thin film transistor Tr2 can include the second semiconductor layer 122, the second gate electrode 124, the second source electrode 126, and the second drain electrode 128.

The overcoat layer 108 can cover the first and second thin film transistors Tr1 and Tr2 and have a substantially flat top surface.

A lower mirror layer 140 can be disposed over the overcoat layer 108 over substantially the entire surface of the substrate 100. That is, the lower mirror layer 140 can be disposed in both the emission areas EA and the laser areas LA of the first, second, and third sub-pixels SP1, SP2, and SP3.

The lower mirror layer 140 can have first and second contact holes 140a and 140b together with the overcoat layer 108. The first contact hole 140a can be disposed in the emission area EA of each sub-pixel SP1, SP2, and SP3 to expose a drain electrode of the first thin film transistor Tr1, that is, the first drain electrode 118 of FIG. 2. The second contact hole 140b can be disposed in the laser area LA of each sub-pixel SP1, SP2, and SP3 to expose a drain electrode of the second thin film transistor Tr2, that is, the second drain electrode 128 of FIG. 2.

As described above, the lower mirror layer 140 can have a structure in which two layers having different refractive indexes are alternately stacked. Specifically, the lower mirror layer 140 can have a structure in which high refractive index layers having a relatively high refractive index and low refractive index layers having a relatively low refractive index are alternately stacked.

For example, the high refractive index layer can be formed of TiO₂, Ta₂O₅, ZrO₂, or ZnS, and the low refractive index layer can be formed of SiO₂, MgF₂, Y₂O₃, or Al₂O₃.

A first pixel electrode 132 and a second pixel electrode 133 can be provided over the lower mirror layer 140. The first pixel electrode 132 can be disposed in the emission area EA of each sub-pixel SP1, SP2, and SP3 and be connected to the first thin film transistor Tr1 through the first contact hole 140a. The second pixel electrode 133 can be disposed in the laser area LA of each sub-pixel SP1, SP2, and SP3 and be connected to the second thin film transistor Tr2 through the second contact hole 140b.

The first pixel electrode 132 can have a triple-layered structure and include a first layer 132a, a second layer 132b, and a third layer 132c. The first layer 132a and the third layer 132c can be transparent electrodes, and the second layer 132b can be a reflective electrode. On the other hand, the second pixel electrode 133 can have a single-layered structure and include one transparent electrode.

A bank 150 can be provided over the first and second pixel electrodes 132 and 133. The bank 150 can cover edges of each of the first and second pixel electrodes 132 and 133 and have first and second openings 150a and 150b exposing central portions of the first and second pixel electrodes 132 and 133, respectively. That is, the first opening 150a can be provided in the emission area EA of each sub-pixel SP1, SP2, and SP3, and the second opening 150b can be provided in the laser area LA of each sub-pixel SP1, SP2, and SP3.

A first light-emitting layer 134 can be provided over the first pixel electrode 132 exposed through the first opening 150a in the emission area EA of each sub-pixel SP1, SP2, and SP3. A second light-emitting layer 135 can be provided over the second pixel electrode 133 exposed through the second opening 150b in the laser area LA of each sub-pixel SP1, SP2, and SP3. The first light-emitting layer 134 and the second light-emitting layer 135 can emit white light.

A common electrode 136 can be provided over the first and second light-emitting layers 134 and 135. The common electrode 136 can be disposed over substantially the entire surface of the substrate 100 and be placed in both the emission area EA and the laser area LA of each sub-pixel SP1, SP2, and SP3.

The common electrode 136 can be transparent or semi-transparent such that light emitted from the first and second light-emitting layers 134 and 135 can be transmitted therethrough.

Next, an upper mirror layer 160 can be provided over the common electrode 136 in the laser area LA of each sub-pixel SP1, SP2, and SP3.

As described above, the upper mirror layer 160 can have a structure in which two layers having different refractive indexes are alternately stacked. Specifically, the upper mirror layer 160 can have a structure in which high refractive index layers having a relatively high refractive index and low refractive index layers having a relatively low refractive index are alternately stacked.

For example, the high refractive index layer can be formed of TiO₂, Ta₂O₅, ZrO₂, or ZnS, and the low refractive index layer can be formed of SiO₂, MgF₂, Y₂O₃, or Al₂O₃.

The upper mirror layer 160 can include first, second, and third mirror layers 160a, 160b, and 160c corresponding to the first, second, and third sub-pixels SP1, SP2, and SP3, respectively. The first, second, and third mirror layers 160a, 160b, and 160c can have different thicknesses. For example, the thickness of the second mirror layer 160b can be smaller than the thickness of the first mirror layer 160a and greater than the thickness of the third mirror layer 160c.

In this case, the thickness of the first mirror layer 160a can be smaller than the thickness of the lower mirror layer 140. Accordingly, the thickness of each of the first, second, and third mirror layers 160a, 160b, and 160c can be smaller than the thickness of the lower mirror layer 140.

In addition, a difference between the refractive indexes of the high refractive index layer and the low refractive index layer of the lower mirror layer 140 can be greater than a difference between the refractive indexes of the high refractive index layer and the low refractive index layer of the upper mirror layer 160, and this will be described in detail later.

Next, an encapsulation layer 180 can be provided over the common electrode 136 of the emission area EA of each sub-pixel SP1, SP2, and SP3 and the upper mirror layer 160 of the laser area LA of each sub-pixel SP1, SP2, and SP3, and a counter substrate 190 can be provided over the encapsulation layer 180.

In addition, a color filter 170 can be provided between the encapsulation layer 180 and the counter substrate 190 in the emission area EA of each sub-pixel SP1, SP2, and SP3. The color filter 170 can include first, second, and third color filters 172, 174, and 176 corresponding to the first, second, and third sub-pixels SP1, SP2, and SP3, respectively. The first, second, and third color filters 172, 174, and 176 can be red, green, and blue color filters, respectively.

As such, in the display device 1000 according to the first embodiment of the present disclosure, the pixel P can include three emission areas EA and the three laser areas LA corresponding to the first, second, and third sub-pixels SP1, SP2, and SP3, so that a color image can be displayed through the emission areas EA at ordinary times and color information can be displayed through the laser areas LA in an emergency situation.

In this case, the laser areas LA of the first, second, and third sub-pixels SP1, SP2, and SP3 can generate red, green, and blue laser beams, respectively. To do this, the first, second, and third mirror layers 160a, 160b, and 160c of the upper mirror layer 160 can have different thicknesses. For example, the thickness of the second mirror layer 160b can be smaller than the thickness of the first mirror layer 160a and greater than the thickness of the third mirror layer 160c.

Meanwhile, the lower mirror layer 140 can be commonly provided in the laser areas LA of the first, second, and third sub-pixels SP1, SP2, and SP3.

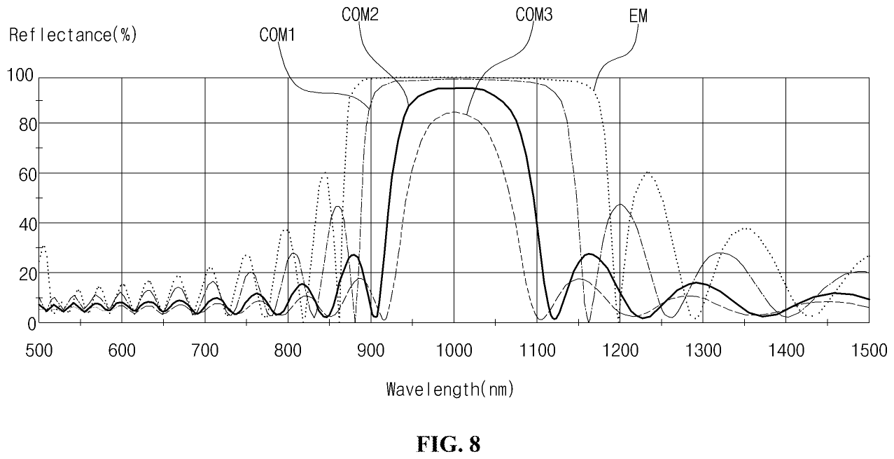

Accordingly, the lower mirror layer 140, desirably, can be made of a combination of materials with a wide high reflection wavelength band. In this case, the lower mirror layer 140 can be formed of a combination of materials with a relatively large difference in refractive indexes, and this will be described with reference to FIG. 8.

FIG. 8 is a graph showing a reflection band of a lower mirror layer according to an embodiment of the present disclosure and shows those of first, second, and third comparative examples. FIG. 8 will be described with reference to FIG. 7.

Here, a difference between the refractive indexes of the high refractive index layer and the low refractive index layer of the lower mirror layer 140 according to the embodiment of the present disclosure EM can be greater than a difference between the refractive indexes of the high refractive index layer and the low refractive index layer of the lower mirror layer according to each of the first, second, and third comparative examples COM1, COM2, and COM3.

For example, based on a wavelength of 1,000 nm, in the embodiment of the present disclosure EM, SiO₂ with a refractive index of about 1.5 can be used as the low refractive index layer of the lower mirror layer 140, and TiO₂ with a refractive index of about 2.25 can be used as the high refractive index layer of the lower mirror layer 140. On the other hand, in the first, second, and third comparative examples COM1, COM2, and COM3, SiO₂ can be used as the low refractive index layer of the lower mirror layer, and ZrO₂ (n=2.04), Y₂O₃ (n=1.77), and Al₂O₃ (n=1.66) can be used as respective high refractive index layers. The high refractive index layers of the first, second, and third comparative examples COM1, COM2, and COM3 can have lower refractive indexes than the high refractive index layer of the embodiment of the present disclosure EM.

As shown in FIG. 8, it can be seen that the reflection band width of the lower mirror layer 140 according to the embodiment of the present disclosure EM is wider than those of the lower mirror layers according to the first, second, and third comparative examples COM1, COM2, and COM3, and it can also be seen that the reflection band width narrows as the difference in the refractive index becomes smaller.

Accordingly, by forming the high refractive index layer and the low refractive index layer of the lower mirror layer 140 using a combination of materials with the relatively large difference in the refractive index, the lower mirror layer 140 can commonly correspond to the first, second, and third sub-pixels SP1, SP2, and SP3.

Therefore, the difference between the refractive indexes of the high refractive index layer and the low refractive index layer of the lower mirror layer 140 can be greater than the difference between the refractive indexes of the high refractive index layer and the low refractive index layer of the upper mirror layer 160.

In addition, the thickness of the lower mirror layer 140, beneficially, can be greater than the thickness of the upper mirror layer 160. Specifically, the thickness of the second mirror layer 160b can be smaller than the thickness of the first mirror layer 160a and greater than the thickness of the third mirror layer 160c, and the thickness of the lower mirror layer 140 can be greater than the thickness of the first mirror layer 160a.

The thickness of each of the lower mirror layer 140 and the first, second, and third mirror layers 160a, 160b, and 160c of the upper mirror layer 160 can be within a range of several micrometers.

For example, TiO₂ can be used as the high refractive index layer of the lower mirror layer 140, SiO₂ can be used as the low refractive index layer of the lower mirror layer 140, ZrO₂ can be used as the high refractive index layer of the upper mirror layer 160, and SiO₂ can be used as the low refractive index layer of the upper mirror layer 160.

In this case, when the red wavelength is 620 nm, the thickness of the first mirror layer 160a of the upper mirror layer 160 can be about 1.8 μm, when the green wavelength is 532 nm, the thickness of the second mirror layer 160b of the upper mirror layer 160 can be about 1.5 μm, and when the blue wavelength is 460 nm, the thickness of the third mirror layer 160c of the upper mirror layer 160 can be about 1.4 μm. In addition, the thickness of the lower mirror layer 140 can be about 2 μm to 4 μm, and preferably can be about 2 μm to 3 μm. However, the embodiments of the present disclosure are not limited thereto.

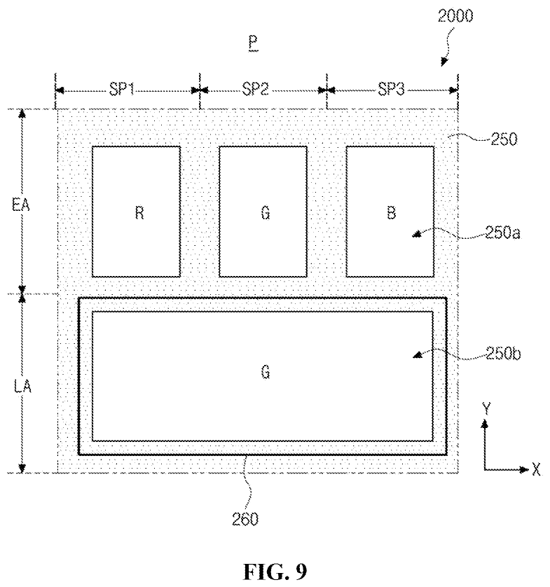

In another embodiment, one pixel can have three emission areas and one laser area. A pixel arrangement structure of a display device according to such a second embodiment of the present disclosure will be described in detail with reference to FIG. 9.

FIG. 9 is a schematic plan view of a display device according to a second embodiment of the present disclosure and mainly shows a bank configuration. FIG. 9 will be described with reference to FIG. 2 together.

As shown in FIG. 9, in the display device 2000 according to the second embodiment of the present disclosure, a pixel P can include at least one emission area EA and at least one laser area LA. In this case, the pixel P can include three emission areas EA and one laser area LA.

More particularly, the pixel P can include first, second, and third sub-pixels SP1, SP2, and SP3 sequentially arranged along a first direction, which is an X direction. For example, the first, second, and third sub-pixels SP1, SP2, and SP3 can be red, green, and blue sub-pixels R, G, and B. Each of the first, second, and third sub-pixels SP1, SP2, and SP3 can include substantially the emission area EA and the laser area LA arranged along a second direction, which is a Y direction.

The emission areas EA of the first, second, and third sub-pixels SP1, SP2, and SP3 can have the same size. However, the embodiments of the present disclosure are not limited thereto. Alternatively, the emission areas EA of the first, second, and third sub-pixels SP1, SP2, and SP3 can have different sizes.

Meanwhile, the laser areas LA of the first, second, and third sub-pixels SP1, SP2, and SP3 can be connected to each other to form one body. Accordingly, the pixel P can have one laser area LA.

The emission areas EA and the laser area LA of the first, second, and third sub-pixels SP1, SP2, and SP3 can be defined by a bank 250. The bank 250 can be disposed between the emission areas EA and between the emission area EA and the laser area LA of the adjacent first, second, and third sub-pixels SP1, SP2, and SP3. In addition, the bank 250 can also be disposed between the emission areas EA and between the laser areas LA of the adjacent pixels P.

The bank 250 can have a first opening 250a corresponding to the emission area EA of each of the first, second, and third sub-pixels SP1, SP2, and SP3 and a second opening 250b corresponding to the laser area LA. That is, the bank 250 can have three first openings 250a and one second opening 250b for one pixel P.

The first and second openings 250a and 250b can define an effective emission area. The first and second openings 250a and 250b are shown as having a rectangular shape with angled corners, but the embodiments of the present disclosure are not limited thereto. Alternatively, the first and second openings 250a and 250b can have various shapes such as a rectangular shape with curved corners, polygonal shapes other than a rectangular shape, or an oval shape.

As described above, each of the first, second, and third sub-pixels SP1, SP2, and SP3 can include the first light-emitting diode De1 in the emission area EA, and the first, second, and third sub-pixels SP1, SP2, and SP3 can include the second light-emitting diode De2 in the laser area LA. Accordingly, the pixel P can include three first light-emitting diodes De1 and one second light-emitting diode De2.

In addition, the first, second, and third sub-pixels SP1, SP2, and SP3 can include the lower mirror layer 140 and the upper mirror layer 260 in the laser area LA. Here, the lower mirror layer 140 can also be provided in the emission areas EA of the first, second, and third sub-pixels SP1, SP2, and SP3. On the other hand, the upper mirror layer 260 can be disposed only in the laser area LA of the first, second, and third sub-pixels SP1, SP2, and SP3 and can be provided as one pattern corresponding to all the first, second, and third sub-pixels SP1, SP2, and SP3.

Here, the upper mirror layer 260 is shown as being patterned to correspond to each pixel P, but the embodiments of the present disclosure are not limited thereto. Alternatively, the upper mirror layers 260 of pixels P adjacent to each other along the first direction can be connected to each other to form one body.

The laser area LA of the display device 2000 according to the second embodiment of the present disclosure can emit a green laser beam with relatively high visibility. However, the embodiments of the present disclosure are not limited thereto.

Meanwhile, although not shown in the figure, the color filter 170 of FIG. 2 can be provided in the emission areas EA of the first, second, and third sub-pixels SP1, SP2, and SP3, and the color filter 170 can include first, second, and third color filters corresponding to the first, second, and third sub-pixels SP1, SP2, and SP3, respectively.

In the display device 2000 according to the second embodiment of the present disclosure, a cross-sectional structure of the emission areas EA of the pixel P can be the same as that of the emission areas EA of the display device 1000 according to the first embodiment shown in FIG. 6. In addition, a cross-sectional structure of the laser area LA of the pixel P of the display device 2000 according to the second embodiment of the present disclosure can be substantially the same as that of the laser area LA of the second sub-pixel SP2 of the display device 1000 according to the first embodiment shown in FIG. 7.

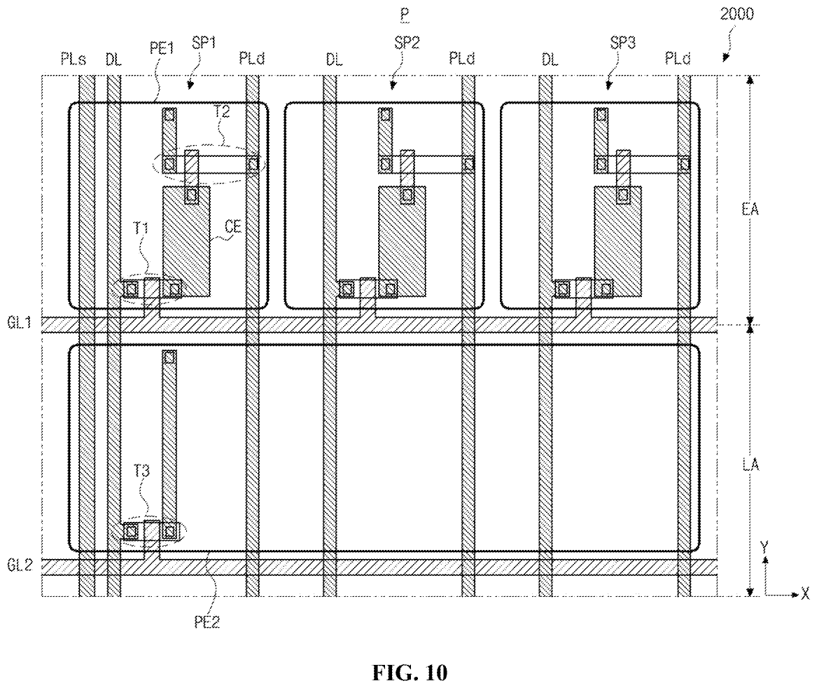

A planar structure of the display device 2000 according to the second embodiment of the present disclosure will be described with reference to FIG. 10.

FIG. 10 is a schematic plan view of a display device according to the second embodiment of the present disclosure and will be described with reference to FIG. 1 together.

As shown in FIG. 10, in the display device 2000 according to the second embodiment of the present disclosure, a first gate line GL1 and a second gate line GL2 can extend in a first direction, which is an X direction, and three data lines DL and three first power lines PLd can extend in a second direction, which is a Y direction. The first gate line GL1 and the second gate line GL2 can cross the data lines DL and the first power lines PLd to define a pixel P including first, second, and third sub-pixels SP1, SP2, and SP3. The three data lines DL and the three first power lines PLd can be alternately arranged along the first direction.

Each of the first, second, and third sub-pixels SP1, SP2, and SP3 can include substantially an emission area EA and a laser area LA. The emission area EA and the laser area LA can be arranged along the second direction. The laser areas LA of the first, second, and third sub-pixels SP1, SP2, and SP3 can be connected to each other to form one body.

In addition, a second power line PLs can extend in the second direction and can cross the first and second gate lines GL1 and GL2. One second power line PLs can be provided for one pixel P. For example, the second power line PLs can be provided on a left side of the first sub-pixel SP1.

Here, the first power line PLd can be a high potential line supplying the high potential voltage VDD of FIG. 1, and the second power line PLs can be a low potential line supplying the low potential voltage VSS of FIG. 1.

A first transistor T1, a second transistor T2, a capacitor electrode CE, and a first pixel electrode PE1 can be provided in the emission area EA of each sub-pixel SP1, SP2, and SP3, and a third transistor T3 and a second pixel electrode PE2 can be provided in the laser area LA corresponding to one of the first, second, and third sub-pixels SP1, SP2, and SP3. For example, the third transistor T3 and the second pixel electrode PE2 can be provided to correspond to the first sub-pixel SP1.

The first transistor T1 can be disposed at a crossing point of each data line DL and the first gate line GL1 and be connected to each data line DL and the first gate line GL1.

The second transistor T2 can be connected to each first power line PLd and the first pixel electrode PE1.

The capacitor electrode CE can be connected to the first and second transistors T1 and T2 and overlap the first pixel electrode PE1, thereby forming a storage capacitor. Alternatively, the capacitor electrode CE can overlap a separate electrode connected to the first pixel electrode PE1, thereby forming a storage capacitor.

The third transistor T3 can be disposed at a crossing point of one of the three data lines DL and the second gate line GL2, for example, at a crossing point of a first data line DL corresponding to the first sub-pixel SP1 and the second gate line GL2, and be connected to the first data line DL and the second gate line GL2. In addition, the third transistor T3 can be connected to the second pixel electrode PE2.

Accordingly, in the display device 2000 according to the second embodiment of the present disclosure, one pixel P can include three first pixel electrodes PE1 and one second pixel electrode PE2. The first transistor T1 of one of the first, second, and third sub-pixels SP1, SP2, and SP3 and the third transistor T3 can be connected to the different first and second gate lines GL1 and GL2 and connected to the same data line DL.

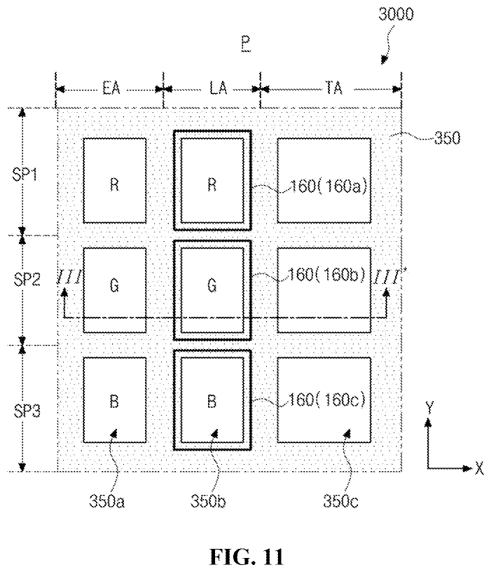

In another embodiment, a display device can further include a transparent area in addition to the emission area and the laser area. A pixel arrangement structure of a display device according to such a third embodiment of the present disclosure will be described in detail with reference to FIG. 11.

FIG. 11 is a schematic plan view of a display device according to a third embodiment of the present disclosure and mainly shows a bank configuration. FIG. 11 will be described with reference to FIG. 2 together. The display device according to the third embodiment of the present disclosure has substantially the same configuration as that of the first or second embodiment, except for having a transparent area. The same or similar parts as the first or second embodiment will be designated by the same or similar references, and explanation for the same parts will be omitted or shortened.

As shown in FIG. 11, in the display device 3000 according to the third embodiment of the present disclosure, a pixel P can include at least one emission area EA, at least one laser area LA, and at least one transparent area TA. In this case, the pixel P can include three emission areas EA, three laser areas LA, and three transparent areas TA.

More particularly, the pixel P can include first, second, and third sub-pixels SP1, SP2, and SP3 sequentially arranged along the second direction, which is the Y direction. For example, the first, second, and third sub-pixels SP1, SP2, and SP3 can be red, green, and blue sub-pixels R, G, and B. Each of the first, second, and third sub-pixels SP1, SP2, and SP3 can include substantially the emission area EA, the laser area LA, and the transparent area TA arranged along the first direction, which is the X direction.

In each of the first, second, and third sub-pixels SP1, SP2, and SP3, the emission area EA and the laser area LA can have the same size, and the transparent area TA can have a larger size than the emission area EA or the laser area LA. Alternatively, the size of the laser area LA can be smaller than the size of the emission area EA, and the size of the transparent area TA can be the same as the size of the emission area EA. However, the embodiments of the present disclosure are not limited thereto.

The emission areas EA, the laser areas LA, and the transparent area TA of the first, second, and third sub-pixels SP1, SP2, and SP3 can be defined by a bank 350. The bank 350 can be disposed between the emission areas EA, between the laser areas LA, between the transparent areas TA, between the emission area EA and the laser area LA, and between the laser area LA and the transparent area TA of the adjacent first, second, and third sub-pixels SP1, SP2, and SP3. In addition, the bank 350 can also be disposed between the emission areas EA, between the laser areas LA, between the transparent areas TA, and between the transparent area TA and the emission area EA of the adjacent pixels P.

The bank 350 can have a first opening 350a corresponding to the emission area EA of each of the first, second, and third sub-pixels SP1, SP2, and SP3 and a second opening 350b corresponding to the laser area LA of each of the first, second, and third sub-pixels SP1, SP2, and SP3. Further, the bank 350 can have a third opening 350c corresponding to the transparent area TA of each of the first, second, and third sub-pixels SP1, SP2, and SP3. That is, the bank 350 can have three first openings 350a, three second openings 350b, and three third openings 350c for one pixel P.

However, the embodiments of the present disclosure are not limited thereto. Alternatively, the second openings 350b and/or the third openings 350c of the first, second, and third sub-pixels SP1, SP2, and SP3 can be connected to each other to form one body. In this case, one pixel P can have three first openings 350a, one second opening 350b, and one third opening 350c. That is, one pixel P can include three emission areas EA, one laser area LA, and one transparent area TA.

The first and second openings 350a and 350b can define an effective emission area, and the third openings 350c can define an effective open area.

As described above, each of the first, second, and third sub-pixels SP1, SP2, and SP3 can include the first light-emitting diode De1 in the emission area EA and the second light-emitting diode De2 in the laser area LA. On the other hand, no light-emitting diode may be provided in the transparent area TA. Accordingly, the pixel P can include three first light-emitting diodes De1 and three second light-emitting diodes De2. Alternatively, when the laser areas LA of the first, second, and third sub-pixels SP1, SP2, and SP3 are connected to each other to form one body, the pixel P can include three first light-emitting diodes De1 and one second light-emitting diode De2.

In addition, each of the first, second, and third sub-pixels SP1, SP2, and SP3 can include the lower mirror layer 140 and the upper mirror layer 160 in the laser area LA. Here, the lower mirror layer 140 can also be provided in the emission areas EA of the first, second, and third sub-pixels SP1, SP2, and SP3 and may not be provided in the transparent areas TA. On the other hand, the upper mirror layer 160 can be provided only in the laser areas LA of the first, second, and third sub-pixels SP1, SP2, and SP3 and can include the first, second, and third mirror layers 160a, 160b, and 160c corresponding to the first, second, and third sub-pixels SP1, SP2, and SP3, respectively.

The laser areas LA of the first, second, and third sub-pixels SP1, SP2, and SP3 can generate red, green, and blue laser beams, respectively. Alternatively, when the laser areas LA of the first, second, and third sub-pixels SP1, SP2, and SP3 are connected to each other to form one body, the laser area LA can generate a green laser beam.

Meanwhile, although not shown in the figure, the color filter 170 of FIG. 2 can be provided in the emission areas EA of the first, second, and third sub-pixels SP1, SP2, and SP3, and the color filter 170 can include the first, second, and third color filters corresponding to the first, second, and third sub-pixels SP1, SP2, and SP3, respectively.

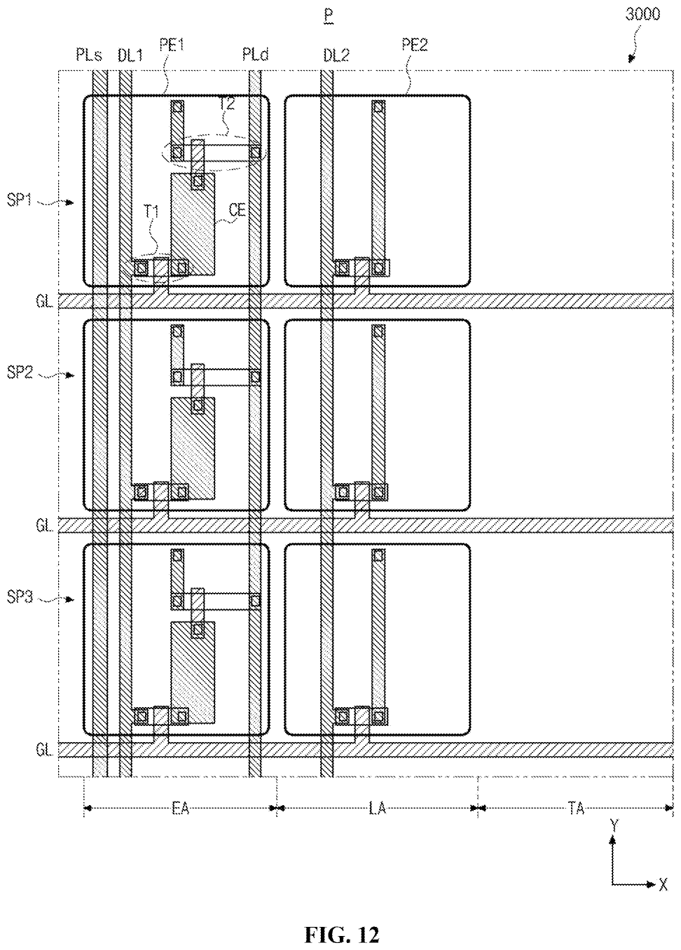

A planar structure of the display device 3000 according to the third embodiment of the present disclosure will be described with reference to FIG. 12.

FIG. 12 is a schematic plan view of a display device according to the third embodiment of the present disclosure and shows one pixel. FIG. 12 will be described with reference to FIG. 1 together.

As shown in FIG. 12, in the display device 3000 according to the third embodiment of the present disclosure, three gate lines GL can extend in a first direction, which is an X direction, and first and second data lines DL1 and DL2, a first power line PLd, and a second power line PLs can extend in a second direction, which is a Y direction. The gate lines GL can cross the first and second data lines DL1 and DL2, the first power line PLd, and the second power line PLs to define a pixel P including first, second, and third sub-pixels SP1, SP2, and SP3. The first, second, and third sub-pixels SP1, SP2, and SP3 can be arranged along the second direction. In addition, the first power line PLd can be disposed between the first and second data lines DL1 and DL2, and the first data line DL1 can be disposed between the first and second power lines PLd and PLs.

Each of the first, second, and third sub-pixels SP1, SP2, and SP3 can include an emission area EA, a laser area LA, and a transparent area TA. The emission area EA, the laser area LA, and the transparent area TA can be arranged along the first direction.

Here, the first power line PLd can be a high potential line supplying the high potential voltage VDD of FIG. 1, and the second power line PLs can be a low potential line supplying the low potential voltage VSS of FIG. 1.

A first transistor T1, a second transistor T2, a capacitor electrode CE, and a first pixel electrode PE1 can be provided in the emission area EA of each sub-pixel SP1, SP2, and SP3, and a third transistor T3 and a second pixel electrode PE2 can be provided in the laser area LA of each sub-pixel SP1, SP2, and SP3.

The first transistor T1 can be disposed at a crossing point of the first data line DL1 and each gate line GL and be connected to the first data line DL1 and each gate line GL. The second transistor T2 can be connected to the first power line PLd and the first pixel electrode PE1.

The capacitor electrode CE can be connected to the first and second transistors T1 and T2 and overlap the first pixel electrode PE1, thereby forming a storage capacitor. Alternatively, the capacitor electrode CE can overlap a separate electrode connected to the first pixel electrode PE1, thereby forming a storage capacitor.

The third transistor T3 can be disposed at a crossing point of the second data line DL2 and each gate line GL and be connected to the second data line DL2 and each gate line GL. In addition, the third transistor T3 can be connected to the second pixel electrode PE2.

Accordingly, in the display device 3000 according to the third embodiment of the present disclosure, one pixel P can include three first pixel electrodes PE1 and three second pixel electrodes PE2. The first transistor T1 and the third transistor T3 can be connected to the same gate line GL and connected to the different first and second data lines DL1 and DL2.

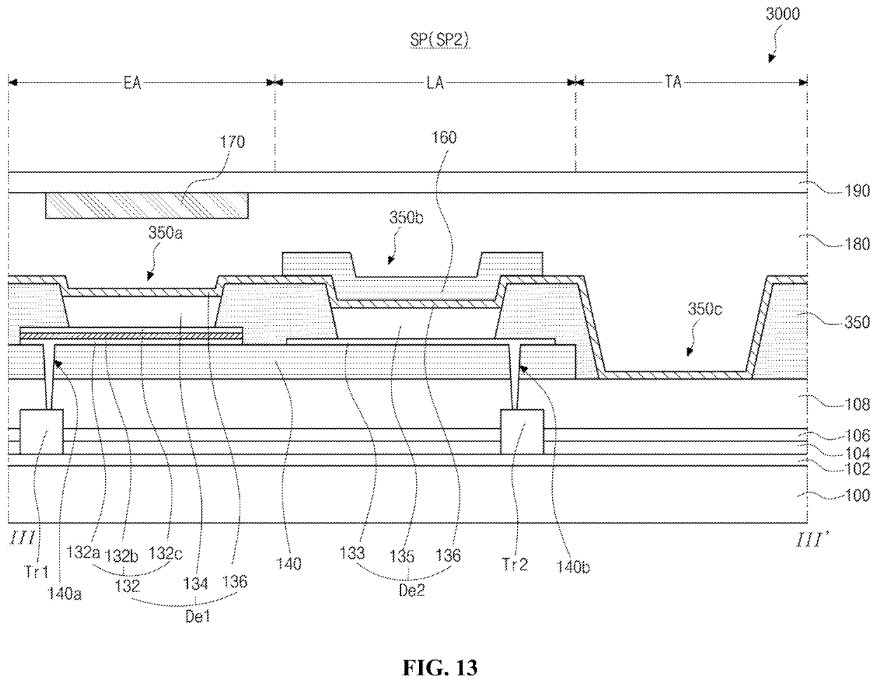

A cross-sectional structure of the emission area EA, the laser area LA, and the transparent area TA of the display device 3000 according to the third embodiment of the present disclosure will be described in detail with reference to FIG. 13.

FIG. 13 is a schematic cross-sectional view of the display device according to the third embodiment of the present disclosure and shows a cross-section corresponding to the line III-III′ of FIG. 11, that is, a cross-section of the second sub-pixel. FIG. 13 will be described with reference to FIG. 11 together. The display device according to the third embodiment of the present disclosure has substantially the same configuration as that of the first or second embodiment, except for having a transparent area. The same or similar parts as the first or second embodiment will be designated by the same or similar references, and explanation for the same parts will be omitted or shortened.

In FIG. 13, the display device 3000 according to the third embodiment of the present disclosure can include at least one pixel P provided over a substrate 100, and the pixel P can include a plurality of sub-pixel SP, that is, first, second, and third sub-pixels SP1, SP2, and SP3. Each of the first, second, and third sub-pixels SP1, SP2, and SP3 can have an emission area EA, a laser area LA, and a transparent area TA.

Specifically, a buffer layer 102 can be provided over the substrate 100. A first thin film transistor Tr1, a second thin film transistor Tr2, and a gate insulation layer 104, a passivation layer 106, and an overcoat layer 108 sequentially stacked can be provided over the buffer layer 102.

The first thin film transistor Tr1 can be disposed in the emission area EA of each of the first, second, and third sub-pixels SP1, SP2, and SP3, and the second thin film transistor Tr2 can be disposed in the laser area LA of each of the first, second, and third sub-pixels SP1, SP2, and SP3. The overcoat layer 108 can be disposed over the first and second thin film transistors Tr1 and Tr2.

A lower mirror layer 140 can be disposed over the overcoat layer 108. The lower mirror layer 140 can be disposed in both the emission areas EA and the laser areas LA of the first, second, and third sub-pixels SP1, SP2, and SP3, but may not be provided in the transparent area TA.

A first pixel electrode 132 and a second pixel electrode 133 can be provided over the lower mirror layer 140. The first pixel electrode 132 can be disposed in the emission area EA of each sub-pixel SP1, SP2, and SP3 and be connected to the first thin film transistor Tr1 through the first contact hole 140a. The second pixel electrode 133 can be disposed in the laser area LA of each sub-pixel SP1, SP2, and SP3 and be connected to the second thin film transistor Tr2 through the second contact hole 140b.

The first pixel electrode 132 can have a triple-layered structure and include a first layer 132a, a second layer 132b, and a third layer 132c. The first layer 132a and the third layer 132c can be transparent electrodes, and the second layer 132b can be a reflective electrode. On the other hand, the second pixel electrode 133 can have a single-layered structure and include one transparent electrode.

A bank 350 can be provided over the first and second pixel electrodes 132 and 133. The bank 350 can have a first opening 350a exposing the first pixel electrode 132 of the emission area EA, a second opening 350b exposing the second pixel electrode 133 of the laser area LA, and a third opening 350c exposing the top surface of the overcoat layer 108 of the transparent area TA. The bank 350 can be in contact with the top and side surfaces of the lower mirror layer 140.

A first light-emitting layer 134 can be provided over the first pixel electrode 132 in the emission area EA of each sub-pixel SP1, SP2, and SP3. A second light-emitting layer 135 can be provided over the second pixel electrode 133 in the laser area LA of each sub-pixel SP1, SP2, and SP3. The first light-emitting layer 134 and the second light-emitting layer 135 can emit white light.

A common electrode 136 can be provided over the first and second light-emitting layers 134 and 135. The common electrode 136 can be disposed over substantially the entire surface of the substrate 100 and be placed in the emission area EA, the laser area LA, and the transparent area TA of each sub-pixel SP1, SP2, and SP3. Accordingly, the common electrode 136 can be in contact with the top surface of the overcoat layer 108 in the transparent area TA. Alternatively, the common electrode 136 can be removed in the transparent area TA.

The first pixel electrode 132, the first light-emitting layer 134, and the common electrode 136 of the emission area EA can constitute the first light-emitting diode De1, and the second pixel electrode 133, the second light-emitting layer 135, and the common electrode 136 of the laser area LA can constitute the second light-emitting diode De2.

Next, an upper mirror layer 160 can be provided over the common electrode 136 in the laser area LA, that is, over the second light-emitting diode De2 in the laser area LA.

As described above, each of the lower mirror layer 140 and the upper mirror layer 160 can have a structure in which high refractive index layers having a relatively high refractive index and low refractive index layers having a relatively low refractive index are alternately stacked.

For example, the high refractive index layer can be formed of TiO₂, Ta₂O₅, ZrO₂, or ZnS, and the low refractive index layer can be formed of SiO₂, MgF₂, Y₂O₃, or Al₂O₃.

Meanwhile, the upper mirror layer 160 can have different thicknesses corresponding to the first, second, and third sub-pixels SP1, SP2, and SP3, respectively. In this case, the thickness of the upper mirror layer 160 in the second sub-pixel SP2 can be smaller than the thickness of the upper mirror layer 160 in the first sub-pixel SP1 and greater than the thickness of the upper mirror layer 160 in the third sub-pixel SP3.

In addition, the thickness of the upper mirror layer 160 can be smaller than the thickness of the lower mirror layer 140. A difference between the refractive indexes of the high refractive index layer and the low refractive index layer of the lower mirror layer 140 can be greater than a difference between the refractive indexes of the high refractive index layer and the low refractive index layer of the upper mirror layer 160.

Next, an encapsulation layer 180 can be provided over the common electrode 136 of the emission area EA, the upper mirror layer 160 of the laser area LA, and the common electrode 136 of the transparent area TA, and a counter substrate 190 can be provided over the encapsulation layer 180.

In addition, a color filter 170 can be provided between the encapsulation layer 180 and the counter substrate 190 in the emission area EA. The color filter 170 can include first, second, and third color filters, for example, red, green, and blue color filters, corresponding to the first, second, and third sub-pixels SP1, SP2, and SP3, respectively.

As such, in the display device 3000 according to the third embodiment of the present disclosure, the pixel P can include three emission areas EA, the three laser areas LA, and three transparent areas TA corresponding to the first, second, and third sub-pixels SP1, SP2, and SP3, so that the surrounding environment information such as backgrounds can be shown together through the transparent areas TA while displaying a color image through the emission areas EA. In addition, color information can be displayed through the laser areas LA in an emergency situation, thereby helping to save lives.

In the present disclosure, each pixel can include the emission area and the laser area. An image can be displayed through the emission area at ordinary times, and in an emergency situation, a laser beam can be generated through the laser area, thereby helping to save lives.

In addition, by applying the top emission type display device, the luminance can be increased, so the power consumption can be reduced, thereby implementing the low power consumption.

Further, the pixel including the emission area and the laser area can be implemented through the existing processes, so that the manufacturing processes can be optimized and the producing energy can be reduced.

Moreover, since each pixel further includes the transparent area, the surrounding environment information such as backgrounds can be shown through the transparent areas while displaying the image information through the emission areas.

It will be apparent to those skilled in the art that various modifications and variations can be made in a device of the present disclosure without departing from the sprit or scope of the embodiments. Thus, it is intended that the present disclosure covers the modifications and variations of this disclosure provided they come within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate provided with a pixel including an emission area and a laser area;
a lower mirror layer over the substrate;
a first light-emitting diode provided in the emission area over the lower mirror layer;
a second light-emitting diode provided in the laser area over the lower mirror layer; and
an upper mirror layer over the second light-emitting diode.

2. The display device of claim 1, wherein the first light-emitting diode includes a first pixel electrode, a first light-emitting layer, and a common electrode,
wherein the second light-emitting diode includes a second pixel electrode, a second light-emitting layer, and a common electrode, and
wherein the common electrode of the first light-emitting diode and the common electrode of the second light-emitting diode are provided as one body.

3. The display device of claim 2, wherein the first pixel electrode reflects light, and the second pixel electrode transmits light.

4. The display device of claim 3, wherein the first pixel electrode has a multi-layered structure including at least one reflective electrode and at least one transparent electrode, and the second pixel electrode has a single-layered structure including a transparent electrode.

5. The display device of claim 1, further comprising a color filter over the first light-emitting diode in the emission area.

6. The display device of claim 1, further comprising:
first and second transistors between the substrate and the first light-emitting diode in the emission area; and
a third transistor between the substrate and the second light-emitting diode in the laser area.

7. The display device of claim 6, wherein the first and third transistors are electrically connected to first and second gate lines, respectively and electrically connected together to one data line.

8. The display device of claim 6, wherein the first and third transistors are electrically connected together to one gate line and electrically connected to first and second data lines, respectively.

9. The display device of claim 1, wherein the pixel includes three emission areas and one laser area.

10. The display device of claim 1, wherein the pixel further includes a transparent area, and the lower mirror layer is not provided in the transparent area.

11. The display device of claim 10, further comprising a bank provided between the emission area and the laser area, between the laser area and the transparent area, and between the transparent area and an emission area of another pixel adjacent to the pixel.

12. The display device of claim 1, wherein the lower mirror layer includes first and second lower refractive index layers having different refractive indexes and alternately stacked,
wherein the upper mirror layer includes first and second upper refractive index layers having different refractive indexes and alternately stacked, and
wherein a difference between the refractive indexes of the first and second lower refractive index layers is greater than a difference between the refractive indexes of the first and second upper refractive index layers.

13. The display device of claim 1, wherein the pixel includes first, second, and third sub-pixels, and each of the first, second, and third sub-pixels includes the emission area and the laser area, and
wherein a thickness of the upper mirror layer of the second sub-pixel is smaller than a thickness of the upper mirror layer of the first sub-pixel and greater than a thickness of the upper mirror layer of the third sub-pixel.

14. A display panel comprising:
a substrate provided with a pixel including an emission area and a laser area;
a lower mirror layer over the substrate;
a first light-emitting diode provided in the emission area over the lower mirror layer;
a second light-emitting diode provided in the laser area over the lower mirror layer; and
an upper mirror layer over the second light-emitting diode.

15. The display panel of claim 1, wherein the first light-emitting diode includes a first pixel electrode, a first light-emitting layer, and a common electrode,
wherein the second light-emitting diode includes a second pixel electrode, a second light-emitting layer, and a common electrode, and
wherein the common electrode of the first light-emitting diode and the common electrode of the second light-emitting diode are provided as one body.

16. The display panel of claim 15, wherein the first pixel electrode reflects light, and the second pixel electrode transmits light.

17. The display panel of claim 16, wherein the first pixel electrode has a multi-layered structure including at least one reflective electrode and at least one transparent electrode, and the second pixel electrode has a single-layered structure including a transparent electrode.

18. The display panel of claim 14, further comprising a color filter over the first light-emitting diode in the emission area.

19. The display panel of claim 14, further comprising:
first and second transistors between the substrate and the first light-emitting diode in the emission area; and
a third transistor between the substrate and the second light-emitting diode in the laser area.

20. The display panel of claim 14, wherein the pixel includes three emission areas and one laser area.
